(19) United States
(12) Patent Application Publication
(10) Pub. No.: US 2016/0300700 A1
(43) Pub. Date: Oct. 13, 2016

(54) Anode Shield

(71) Applicant: Vision Ease, LP, Ramsey, MN (US)

(72) Inventors: Michael Marshall, Andover, MN (US); Jeff Brown, St. Louis Park, MN (US)

(73) Assignee: Vision Ease, LP, Ramsey, MN (US)

(21) Appl. No.: 15/073,552

(22) Filed: Mar. 17, 2016

Related U.S. Application Data
(60) Provisional application No. 62/135,057, filed on Mar. 18, 2015.

(51) Int. Cl. H01J 37/34

(52) U.S. Cl. CPC H01J 37/3441; H01J 37/3438; H01J 37/3447; H01J 37/345; H01J 2237/026; H01J 2237/3323

(57) ABSTRACT

A sputter system and an anode and anode shield assembly that provide for improved grounding for extended sputter cycles.

### RELATED APPLICATIONS

This application claims benefit of and priority to U.S. Provisional Application Ser. No. 62/135,057 filed Mar. 18, 2015, entitled Anode Shield, which is hereby incorporated herein by reference in its entirety.

### FIELD OF THE INVENTION

The present invention relates to coating systems and methods of use of the same and, more particularly, to the shielding of anodes in coating systems.

### BACKGROUND OF THE INVENTION

Physical vapor deposition techniques and machines are often employed for the depositing or coating of thin films on to articles or substrates, such as ophthalmic lenses, safety shields, and windows, through the condensation of a vaporized form of a desired coating material onto the article or substrate. One variety of a physical vapor deposition is sputtering or sputter coater. Sputter coating employs a glow plasma discharge that bombards the desired coating material source or “target” and thereby sputters portions of the material away from the target in the form of vapor for subsequent deposition on to the article or substrate. The glow plasma discharge is often localized around the target by a magnet.

One application of a sputter coater is for the formation of anti-reflective coatings on optical articles or substrates such as ophthalmic lenses. Anti-reflective coatings reduce reflection off the front and back surfaces of ophthalmic lenses and therefore are desirable for creating eyeglasses with improved light transmission, visibility, and aesthetics. Typically, such anti-reflective coatings are applied as one or more layers having a precise and relatively thin thickness.

One problem with conventional or known sputter box coaters is that an oxide form of the desired coating material or materials can build-up or form over an interior of the sputter chamber thereby masking or insulating the interior of the sputter chamber area around the system cathode. In these systems a continuous electric circuit is formed from the target cathode surface, through the plasma, and to an anode plane. In many systems the anode plane is the chamber itself which is held to ground potential. This oxide layer can eventually impede the electrons in the plasma from finding the anode of the power supply which is commonly the electrical ground of the chamber. Over time, as the oxide layer gets thicker the electrons in the plasma are increasingly less efficient and successful in finding electrical ground. This adversely affects power delivery through the target. This, in turn, affects the deposition rate and uniformity of the sputtered film and the entire sputtering process becomes less predictable and uniform.

This problem is further described by Seller, Jeff C., The disappearing anode myth: strategies and solutions for reactive PVD from single magnetrons,” Surface and Coatings Technology, 94-95, 184-188 (1997). U.S. Pat. No. 6,495,000 describes employing a finned anode design and/or magnetic arrays to redirect electron flow and combat the above-described anode effect during the formation of liquid crystal displays. U.S. Pat. No. 4,946,576 describes employing a system of anode shutters to combat the anode effect, and U.S. Pat. No. 7,850,828 describes employing a gas manifold and magnets to confine and redirect electrons in order to protect the system anode from sputtered dielectric material during the deposition process. Each of the above references are hereby incorporated herein by reference in their entirety.

However, each of these previously proposed solutions to the above-described anode effect is either directed to relatively large application sputter boxes or to solutions requiring a relatively large foot print within a sputter chamber. In small coating chambers used, for example for the coating of ophthalmic lenses in prescription labs, the system sensitivity to this anode effect is exaggerated due to the small starting surface area, the almost exclusive use of insulating oxides and nitrides, and the inclusion of electrically floating components to hold the substrate in an attempt to reduce heating effects and surface arcing.

Furthermore, in such small coating systems, material build-up and the resulting loss of an anode can result in unwanted heating of the substrates being coated and/or substrate holder due to the plasma extending to other areas of the chamber. For substrates such as plastic ophthalmic lenses the increase in temperature is very detrimental and can also pose a safety issue for operators needing to handle the substrate holder. The loss of the anode will also require chamber maintenance to clean surfaces and restore the electrical continuity from the target to the anode. Accordingly, any means of establishing an improved anode protected from deposition will reduce required maintenance and improve uptime and overall throughput. Prior proposed solutions to these problems are not feasible for implementation in such small sputter chambers.

What is needed in the art is a device and method for effectively maintaining the availability of the positive side of the power supply, which may or may not be at ground potential, to the plasma within a small sputter chamber.

### OBJECTS AND SUMMARY OF THE INVENTION

The system, assemblies, and methods of the present invention maintain the availability of a positive side of a power supply to the plasma within a sputter chamber. These objectives are achieved, in part, by providing a sputter system comprising: a target; a chamber; an anode positioned between the target and the chamber; and a shield positioned between the target and the anode. In certain embodiments of the present invention, the anode comprises a surface texture that increases the surface area of at least a portion of the anode.

These objectives are achieved, in part, by providing an anode arrangement comprising: a target mask protruding at least partially into a sputter path, the target mask having a first longitudinal side and a second longitudinal side; an anode shield positioned between the target mask and a target; and a space formed between the target mask and the anode shield having a thickness of approximately 0.5 to 1.5 millimeters.

These objectives are achieved, in part, by providing a method for shielding an anode of a sputter system comprising the steps of: interposing an anode between a sputter target and a sputter chamber; interposing an anode shield between the sputter target and the anode; and forming a gap of approximately 0.5 to 1.5 millimeters between a surface of the anode and a surface of the anode shield.

### BRIEF DESCRIPTION OF THE DRAWINGS

These and other aspects, features and advantages of which embodiments of the invention are capable of will be apparent and elucidated from the following description of embodiments of the present invention, reference being made to the accompanying drawings, in which

FIG. 1 is a sectional perspective view of a system according to one embodiment of the present invention.

FIG. 2 is a front elevation view of a target mask according to one embodiment of the present invention.

FIG. 3 is a perspective view of a target mask according to one embodiment of the present invention.

FIG. 4 is a back elevation view of a target mask according to one embodiment of the present invention.

FIG. 5 is a side elevation view of a target mask according to one embodiment of the present invention.

FIG. 6 is a sectional view along line A-A of FIG. 2 of a target mask according to one embodiment of the present invention.

FIG. 7 is an enlarged sectional view of area B of FIG. 6 of a portion of a target mask according to one embodiment of the present invention.

FIG. 8 is a front elevation view of an anode shield according to one embodiment of the present invention.

FIG. 9 is a side elevation view of an anode shield according to one embodiment of the present invention.

FIG. 10 is a partial front elevation view of a target mask according to one embodiment of the present invention.

FIG. 11 is a front elevation view of a target mask and an anode shield according to one embodiment of the present invention.

FIG. 12 is a front elevation view of a target mask and an anode shield according to one embodiment of the present invention.

FIG. 13 is a front elevation view of a target mask and an anode shield according to one embodiment of the present invention.

FIG. 14 is a chart showing a measured voltage at a target over a series of sequentially performed coating cycles for a system according to one embodiment of the present invention.

FIG. 15 is a chart showing a measured voltage at a target over a series of sequentially performed coating cycles for a system according to one embodiment of the present invention.

### DESCRIPTION OF EMBODIMENTS

Specific embodiments of the invention will now be described with reference to the accompanying drawings. This invention may, however, be embodied in many different forms and should not be construed as limited to the embodiments set forth herein; rather, these embodiments are provided so that this disclosure will be thorough and complete, and will fully convey the scope of the invention to those skilled in the art. The terminology used in the detailed description of the embodiments illustrated in the accompanying drawings is not intended to be limiting of the invention. In the drawings, like numbers refer to like elements.

Broadly speaking, the present invention provides devices and methods for effectively maintaining access from a negative (cathode) surface through a plasma to the positive side (anode, often a ground) of the power supply within a sputter chamber. Accordingly, the devices and methods of the present invention provide for improved grounding for extended periods of sputter chamber use. This is achieved, in part, by a target mask and an anode shield assembly that creates a space between the mask and anode shield. The shield functions to protect a portion of the mask that functions as a system anode from oxide layer build-up and thereby allows substantially unhindered or unmasked access of the plasma to the anode for grounding.

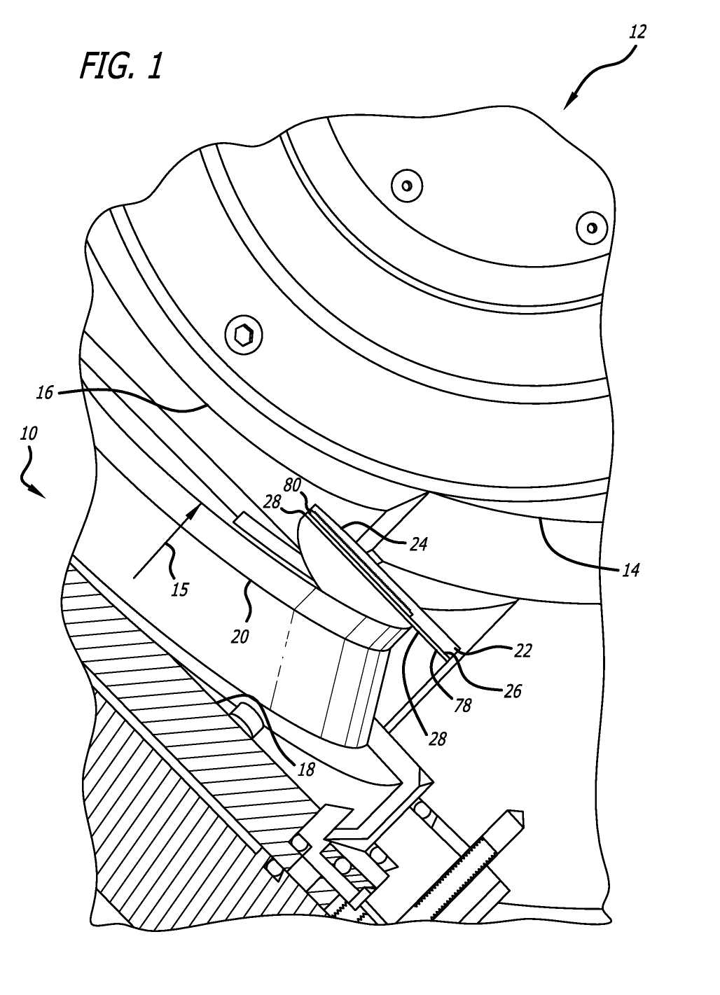

With reference to FIG. 1, in certain embodiments of the present invention, a sputter coating system 10 incorporates a chamber 12 and a chamber liner 14 through which a target window 16 is formed. A longitudinal surface of a target 18 is in approximate alignment with the chamber window 16. The target 18 may be in the shape of a relatively thin cylinder having approximately planar front and back longitudinal surfaces. Positioned between the target 18 and the chamber liner 14 is a liner 20 to which a target mask 22 having a first side 24 and a second side 26 is attached. In certain embodiments, at least a portion of an anode shield 28 is incorporated between the liner 20 and the second side 26 of the target mask 22.

In certain embodiments, the target 18, target mask 22, and the anode shield 28 are positioned within independent planes that are substantially parallel to one another. At least a portion of the target mask 22 and a portion of the anode shield 28 protrude into a sputter path 15 between the target 18 and the chamber liner 14. In certain embodiments, the substantially parallel planes of the target 18, target mask 22, and the anode shield 28 are oriented substantially perpendicular to the sputter path 15. Additional aspects of an exemplary sputter system according to the present invention are detailed in the Assignee's U.S. Publication No. 2014/0174912 which is hereby incorporated herein by reference in its entirety.

It will be appreciated that the sectional view of FIG. 1 only shows a portion of the system 10 and only portions of the above described components. For example, in certain embodiments, while the target mask 22 and the anode shield 28 are referenced in the singular, at least these components are incorporated in the system 10 in pairs. Alternatively stated, the system 10 employs two symmetrically or asymmetrically positioned target masks 22 and anode shields 28 for each sputter source in the system.

It will further be appreciated that the described dimensions of the various portions of the components of the system 10 of the present invention are provided by way of example only. One skilled in the art will appreciate that variations in the dimensions and the shape of such components are contemplated and within the scope of the present invention.

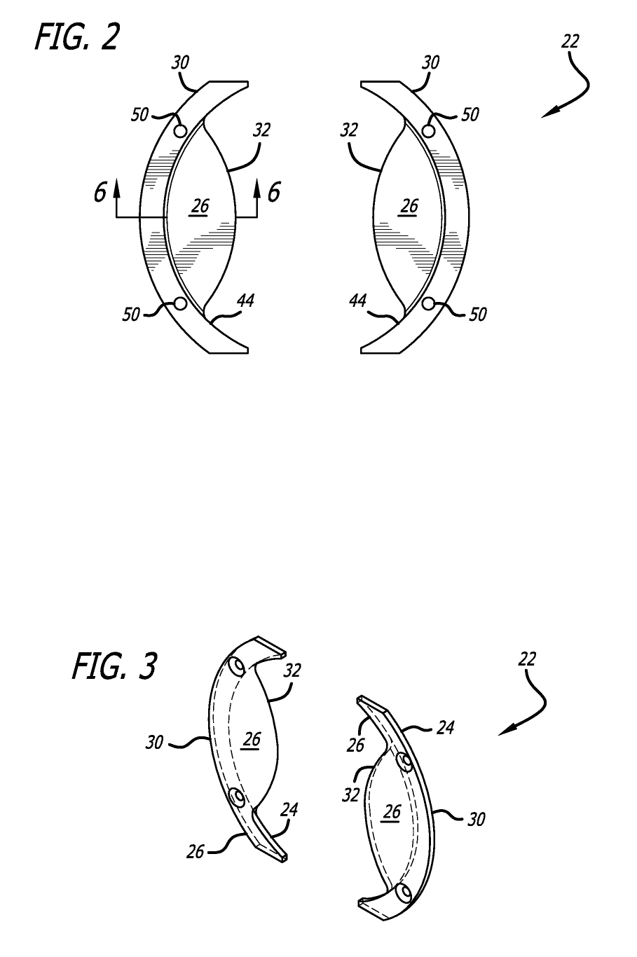

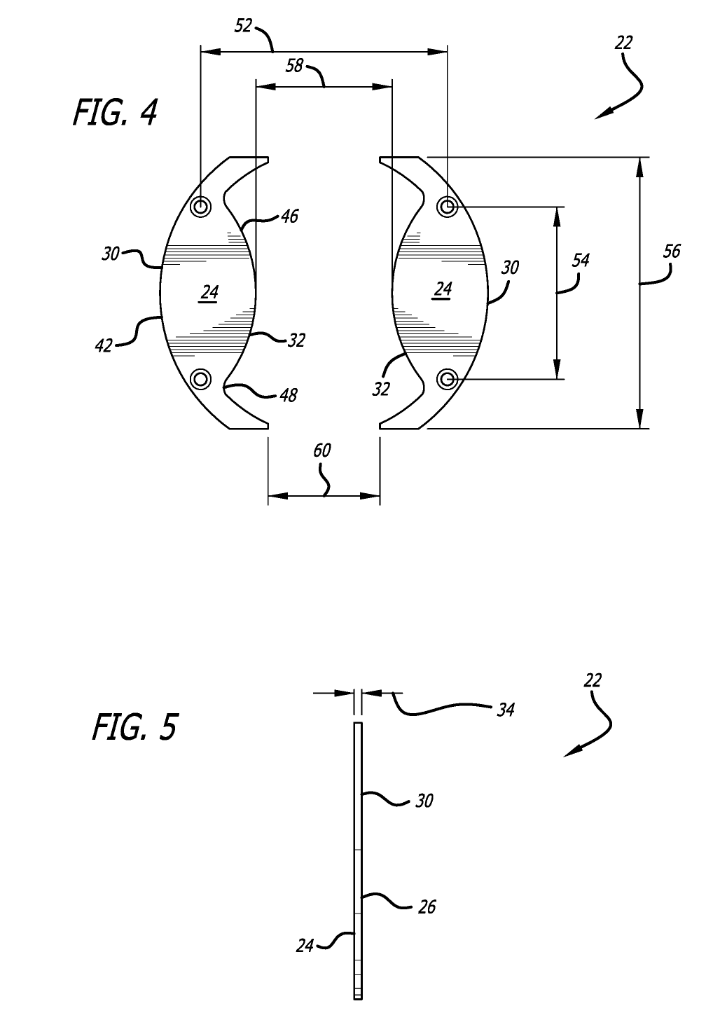

With reference to FIGS. 2-7, in certain embodiments of the present invention, the target mask 22 has a relatively thin substantially planar form. The target mask 22 incorporates a rim portion 30 and an inner portion 32. The rim portion 30 has, for example, a rim thickness 34 of approximately 0.118 inches. The rim portion 30 of the target mask 22 defines an outer rim arch 42 having a radius of approximately 2.854 inches. A length 56 of the target mask 22 is approximately 4.646 inches. When the pair of target masks 22 are installed in a system 10 according to the present invention, the rim portions 30 of the pair of masks 22 are separated from one another by a length 60 of approximately 1.969.

The inner portion 32 of the target mask 22 projects from the rim portion 30, thereby defining an arch 46 having a radius of approximately 2.363 inches. In operation, the inner portion 32 of the target mask 22 functions as an anode or ground for the system 10. When the pair of target masks 22 are installed in a system 10 according to the present invention, the inner portions 32 of the pair of masks 22 are separated from one another by a length 58 of approximately 2.361 inches.

In certain embodiments, the target mask 22 incorporates holes 50 through which insertion hardware, such as screws or bolts, are inserted for mounting the target mask to, for example, the liner 20. The holes 50 on an individual target mask 22 are separated from one another by a length 54 of approximately 2.937 inches. When the pair of target masks 22 are installed in a system 10 according to the present invention, the corresponding holes 50 on each of the different masks 22 are separated from one another by a length 52 of approximately 4.311 inches.

In certain embodiments, as shown at least in FIGS. 1, 6, and 7, the second side 26 of the inner portion 32 of the target mask 22 forms a recess 36 relative to the second side 26 of the rim portion of the target mask 22. The recess 36 has, for example, a thickness 38 of approximately 0.030 inches. An intersection of the rim portion 30 and the recess 36 of the inner portion 32 defines an inner rim arch 44 of approximately 2.441 inches. An intersection of the inner rim arch 44 of the rim portion 30 and the arch 46 of the inner portion 32 defines an arch 48 having, for example, a radius of 0.213 inches.

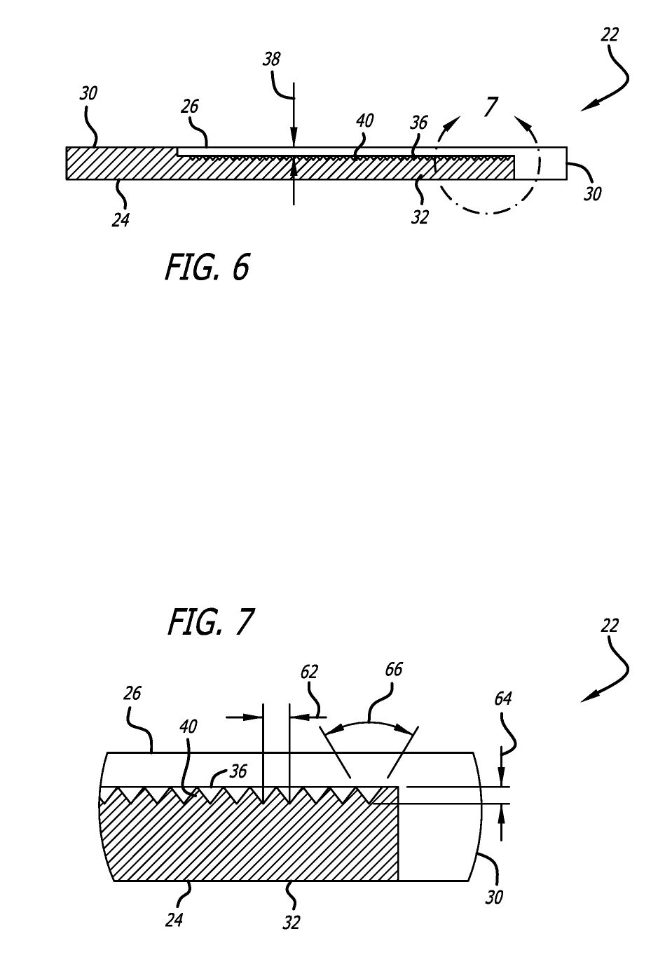

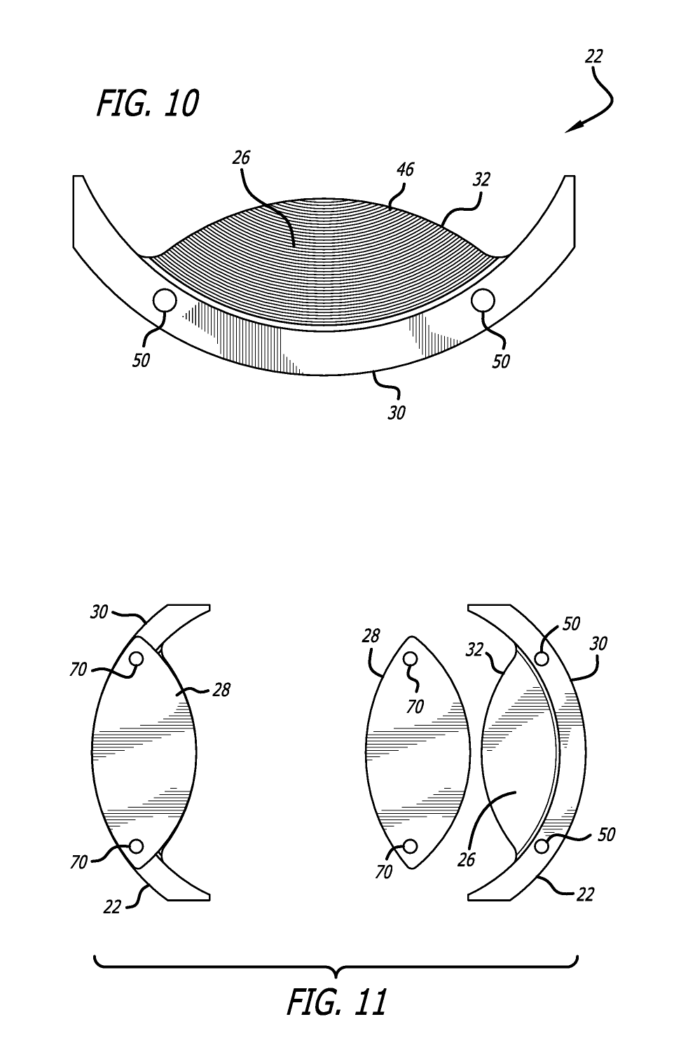

As shown in at least FIGS. 6, 7, and 10, in certain embodiments, the second side 26 of the inner portion 32 of the target mask 22 incorporates a texture 40, i.e. the second side 26 of the inner portion 32 of the target mask 22 is not smooth. For example, the texture 40 may be in the form of linearly formed rows of peaks and valleys or troughs, e.g. linear rows of teeth. The linear form of the texture 40 may be arched so as to substantially track the arch 44 of the rim portion 30 of the target mask 22 over the entire or substantially the entire side 26 of the inner portion 32, as shown in FIG. 10. Immediately adjacent individual troughs of the texture 40 are, for example, separated from one another by a length 62 of approximately 0.025 inches. A depth 64 of the troughs of the texture 40 is, for example, approximately 0.020 inches, and an angle 66 formed by the side walls of the troughs of the texture 40 is, for example, approximately 60 degrees.

In certain embodiments, the texture 40 may be in the form of a regular or irregular linear peak and valley pattern or may take any other form that increases the surface area of the inner portion 32 of the target mask 22. The recess 36 and the texture 40 may function to facilitate unimpeded access of the plasma to the inner portion 32 of the target mask 22. In certain embodiments of the present invention, the side 26 of the inner portion 32 is smooth, i.e. is not textured.

In certain embodiments, the target mask 22 is formed of, for example, a metal such as aluminum or 6061-T6 aluminum; a stainless steel such as 316 or 304 grade or Titanium alloys.

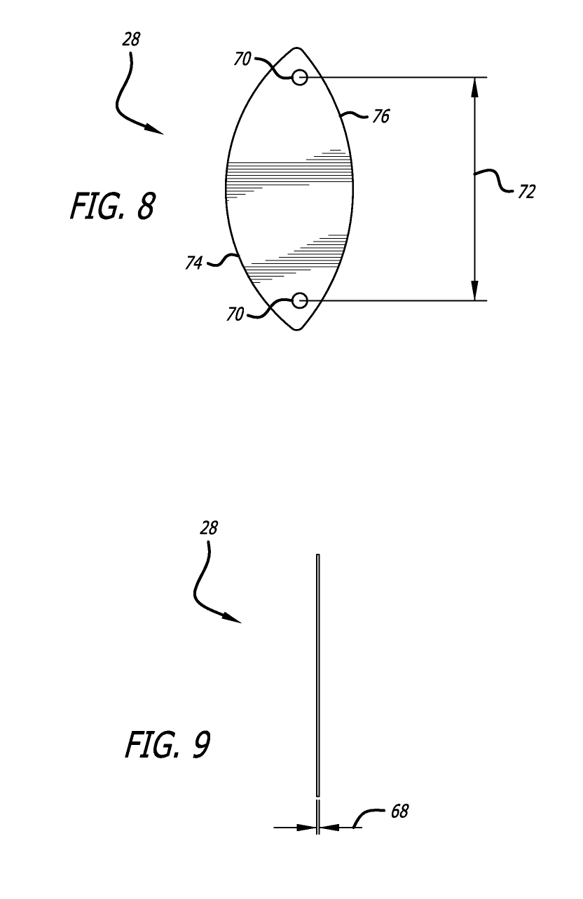

Turning next to the anode shield 28 of the present invention, with reference to FIGS. 8 and 9, in certain embodiments, the anode shield 28 has the general form of a planar prolate spheroid or football-like shape that is either symmetric or asymmetric. A first radius 74 of the anode shield 28 is, for example, 2.363 inches, and a second radius 76 of the anode shield 28 is, for example, 2.854 inches. The anode shield 28 has a thickness 68 of, for example, approximately 0.03 inches.

When mounted within system 10, the anode shield 28 is attached to the system 10 by pinching a periphery portion 78 of the anode shield 28 between the second side 26 of the rim portion 30 of the target mask 22 and a surface of the liner 20. The remainder of the anode shield 28 that is not held or pinched between the second side 26 of the rim portion 30 and a surface of the liner 20 extends over and covers all or a portion of the second side 26 of the inner portion 32 of the target mask 22. Due to the recess 36 formed on the second side 26 of the inner portion 32 of the target shield 22, a space or gap 80 is formed between second side 26 of the inner portion 32 of the target shield 22 and the anode shield 28, as shown in FIG. 1. The space or gap 80 is, for example, in the range of approximately 0.02 to 0.06 inches or 0.5 to 1.5 millimeters.

In certain embodiments, the anode shield 28 incorporates holes 70 through which insertion hardware, such as screws or bolts, are inserted for mounting the anode shield 28 to, for example, the liner 20. The holes 70 on an individual anode shield 28 are separated from one another by a length 72 of approximately 2.937 inches. The spacing of the holes 70 of the anode shield 28 and the spacing of the holes 50 of the target mask 22 are substantially identical such that mounting hardware can be simultaneously inserted through a corresponding hole 50 and hole 70 during assembly of the system 10.

In certain embodiments of the present invention, the anode shield 28 and the target mask 22 are shaped and sized such that the anode shield 28 covers or substantially covers an entirety of the side 26 of the inner portion 32 of the target mask 22, as shown in FIG. 1. In certain alternative embodiments, the anode shield 28 does not cover or substantially cover an entirety of the side 26 of the inner portion 32 of the target mask 22. For example, as shown in FIG. 11, the anode shield 28 does not cover a portion of the inner portion 32 of the target mask 22 along the radius 46 of the inner portion 32 of the target mask 22.

In operation, the space or gap 80 formed between second side 26 of the inner portion 32 of the target shield 22 and the anode shield 28 allows for the unobstructed access of the plasma to the inner portion 32 of the target mask 22. Since the anode shield 28 covers and shields at least a portion of inner portion 32 of the target mask 22, which functions as an anode or ground for the system 10, the system 10 of the present invention effectively blocks all or a substantial portion of the material sputtered from the target 18 from depositing and building upon the inner portion 32 of the target mask 22, i.e. the system anode.

In certain embodiments, the anode shield 28 is formed of, for example, a metal, a stainless steel, or 304 stainless steel. Such shields can also be made from high strength materials such as Titanium alloys.

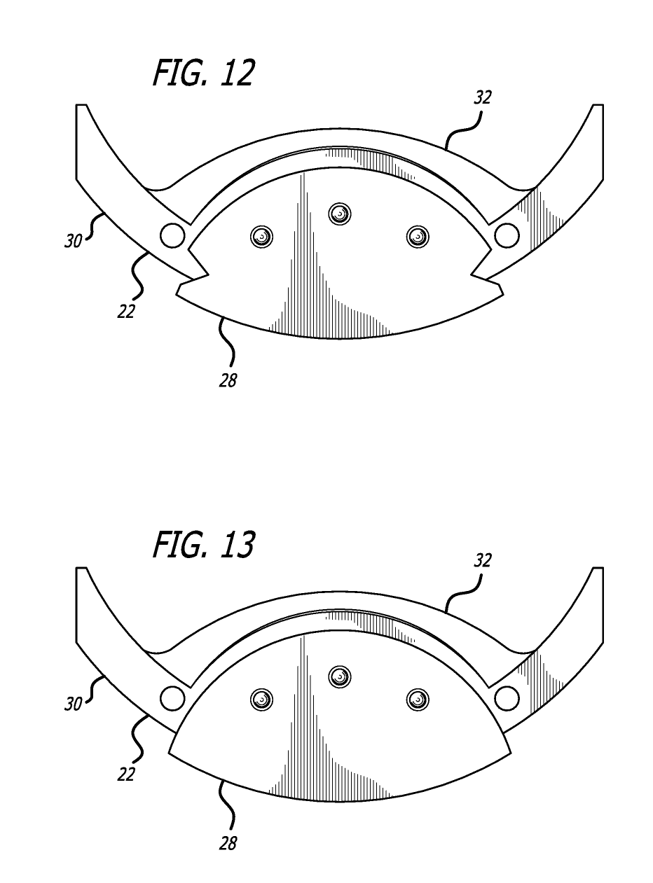

In certain embodiments of the present invention, as shown in FIGS. 12 and 13, the anode shield may not rest upon or attach to the rim portion of the target mask as described above. As shown in FIG. 10, alternatively, the target shield may rest directly upon the textured or non-textured surface of the inner portion of the target mask. The space or gap between the inner portion of the target mask and the anode shield may be formed by providing features that protrude from either of the target mask and the anode shield and thereby hold the target mask and the anode shield apart from one another. For example, such features may take the form of projections extending from the back surface of the shield. Such projections can take the form of dimples on the surface which form point contacts between the anode shield 28 and the inner portion 32 of the target mask 22. Such projections allow the target mask to not require a recess 36. Such projections may also assist in controlling deformation of the anode shield due to accumulated coating material by limiting the possible amount of deflection into the target mask.

While the above-described embodiments disclose shielding a portion of the target mask of the sputter coating system, it is contemplated that other interior portions of the sputter system may also function as an anode and thereby ground the sputter system. Hence, the shielding and formation of a space or gap for the ingress of plasma to other grounding structure or structures present within a sputter coating system is also contemplated and within the scope of the present invention. In certain embodiments, the anode shield is incorporated into a deposition shielding used to prevent coating of the sputter chamber walls.

In certain embodiments, the anode shield is incorporated into the magnetron sputtering source providing an isolated closed circuit path that operates completely independent of the sputter chamber wall. In certain embodiments, the anode of the system and the power supply may not be electrically grounded. In such cases the anode shielding would be electrically isolated from ground and directly connected via wiring to the power supply anode. Isolation from ground may be accomplished by employing insulating standoffs or blocks formed of, for example, ceramic materials.

### EXAMPLES

In order to evaluate the efficacy of the system of the present invention, system voltage was monitored for a “test” sputter coating system employing an anode and an anode shield according to the present invention. The test system was configured with an anode shield that formed a gap or space of approximately 1 millimeter between a surface of the anode shield and a surface of the anode. This test assembly was configured for both the low refractive index silicon target and the high refractive index zirconium target employed within the system. System voltage was also monitored for a “control” sputter coating system not employing an anode and an anode shield according to the present invention. Since the operating voltage is an excellent indicator of process stability, systems voltage was measured for the test system and the control system at each of the systems' respective targets over a series of sequentially performed coating cycles.

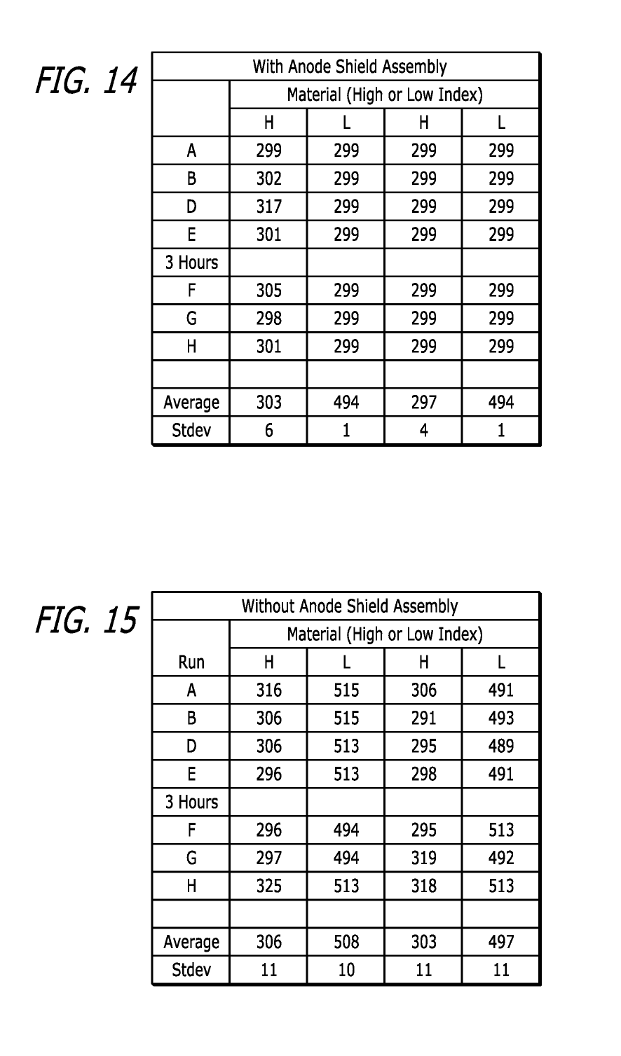

FIG. 14 shows the measured voltages of the study for the test system, and FIG. 15 shows the measured voltages of the study for the control system. The measured voltage is the average voltage recorded over each layer. The average is calculated by the control software which records the voltage every 1 second or less and reports the calculated average. The most left columns of FIGS. 14 and 15 represent different coating cycles A-E and F-H for which voltages were measured. In order to obtain an evaluation over an extended run time, between cycles A-E and F-H, each system was continuously run for approximately three hours so as to perform approximately 10-15 coating cycles. During this three hour period, indicated as “3 Hours” in FIGS. 14 and 15, voltage measurements were not recorded.

FIG. 14 shows a very small change in the operating voltage (for power control mode) over an extended use for the test system employing anode shielding according to the present invention. In contrast, FIG. 15 shows a relatively large change in the voltage over the same extended use for the control system, not employing anode shielding according to the present invention. Comparison of the measured voltages of the test and control system demonstrates a substantial improvement in the process stability of the test system employing the anode shielding of the present invention. The results showed more stability of the plasma with only a 1 to 2 volt change for the low refractive index material in the test system in contrast to a 5 to 10 volts change over use for the low refractive index material in the control system.

The high refractive index material also showed improved stability in the test system employing the anode shields with a reduction by a factor of approximately 2 in the variation of the operating voltage compared control system not employing the anode shielding. Such improvements in stability result in improved repeatability in the coating process and increased time durations between system maintenance due to loss of the anode surface.

Although the invention has been described in terms of particular embodiments and applications, one of ordinary skill in the art, in light of this teaching, can generate additional embodiments and modifications without departing from the spirit of or exceeding the scope of the claimed invention. Accordingly, it is to be understood that the drawings and descriptions herein are proffered by way of example to facilitate comprehension of the invention and should not be construed to limit the scope thereof.

What is claimed is:

1. A sputter system comprising:
a target;
a chamber;
an anode positioned between the target and the chamber; and
an anode shield positioned between the target and the anode.

2. The system of claim 1 wherein the target comprises a longitudinal surface positioned substantially with in a single plane.

3. The system of claim 1 wherein the target comprises silicon or zirconium.

4. The system of claim 1 wherein the anode comprises a longitudinal surface positioned within a plane that is substantially parallel to the plane of the surface of the target.

5. The system of claim 1 wherein the anode comprises a rim portion that has a thickness greater than a thickness of an inner portion of the anode.

6. The system of claim 1 wherein the anode comprises a surface texture.

7. The system of claim 1 wherein the anode comprises a surface formed of linear peaks and valleys.

8. The system of claim 1 wherein the anode shield comprises a longitudinal surface positioned within a plane that is substantially parallel to the plane of the surface of the target and the plane of the surface of the anode.

9. The system of claim 1 wherein the anode shield is positioned closer to the anode than the target.

10. The system of claim 1 wherein a gap of approximately 0.5 to 1.5 millimeters is formed between a surface of the anode and a surface of the shield.

11. An anode arrangement comprising:
a target mask protruding at least partially into a sputter path, the target mask having a first longitudinal side and a second longitudinal side;
an anode shield positioned between the target mask and a target; and
a space formed between the target mask and the anode shield having a thickness of approximately 0.5 to 1.5 millimeters.

12. The arrangement of claim 11 wherein the target mask comprises an anode.

13. The arrangement of claim 11 wherein the target mask comprises a rim having a thickness that is greater than a thickness of an inner portion of the target mask.

14. The arrangement of claim 13 wherein the anode shield is positioned directly against the first longitudinal surface of the rim of the target mask.

15. The arrangement of claim 11 wherein at least a portion of the first longitudinal surface comprises a texture that increases the surface area of the first longitudinal surface relative to a surface area of the second longitudinal surface.

16. A method for shielding an anode of a sputter system comprising the steps of:
interposing an anode between a sputter target and a sputter chamber;
interposing an anode shield between the sputter target and the anode; and
forming a gap of approximately 0.5 to 1.5 millimeters between a surface of the anode and a surface of the anode shield.

17. The method of claim 16 wherein the step of interposing an anode between a sputter target and a sputter chamber comprises positioning a longitudinal surface of the anode in a plane that is substantially parallel to a longitudinal surface of the sputter target.

18. The method of claim 16 wherein the step of interposing an anode between a sputter target and a sputter chamber comprises interposing a texture surface of the anode between a sputter target and a sputter chamber.

19. The method of claim 16 wherein the step of interposing an anode shield between the sputter target and the anode comprises positioning a longitudinal surface of the anode shield in a plane that is substantially parallel to a longitudinal surface of the anode.

20. The method of claim 16 wherein the step of interposing an anode shield between the sputter target and the anode comprises covering an entirely of a longitudinal surface of the anode exposed to the sputter target with the anode shield.
